(19) United States
(12) Patent Application Publication
(10) Pub. No.: US 2026/0256014 A1
(43) Pub. Date: Aug. 27, 2026

(54) CAPILLARY HEAD WITH NONCIRCULAR CONE FOR WIREBONDING IN SEMICONDUCTOR PACKAGE MANUFACTURING

(71) Applicant: TEXAS INSTRUMENTS INCORPORATED, Dallas, TX (US)

(72) Inventors: Ye Zhuang, Chengdu (CN); Xiao Lin Kang, Chengdu (CN); Yu Yang, Chengdu (CN); Yajun Zhang, Chengdu (CN)

(21) Appl. No.: 19/062,565

(22) Filed: Feb. 25, 2025

(51) Int. Cl. H01L 23/00; H01L 21/56

(52) U.S. Cl. CPC H10W 74/016; H10W 74/014; H10W 72/0198; H10W 72/07141; H10W 72/075; H10W 72/07523; H10W 72/07533; H10W 72/07555; H10W 72/531; H10W 72/536; H10W 72/5363; H10W 72/5522; H10W 72/5524; H10W 72/5528; H10W 72/923; H10W 72/925; H10W 72/952; H10W 90/754; H10W 90/756

(57) ABSTRACT

A semiconductor die may include a bond pad and a wire attached to the bond pad by an intermetallic compound. A first portion of the wire in direct contact with the bond pad has a first perimeter, a second portion of the wire not in direct contact with the bond pad has a second perimeter that is smaller than the first perimeter, a third portion of the wire between the first portion and the second portion has a third perimeter, and a first Euclidean distance between two opposing points on the third perimeter is longer than a second Euclidean distance between two other opposing points on the third perimeter.

### BACKGROUND

Wirebonding is one of the processes used in semiconductor package fabrication. It is used to establish electrical connections between a semiconductor chip and its package or external circuitry. In wire bonding, fine gold, copper, or aluminum wires are typically used to form bonds between the semiconductor die's bond pads and the package substrate. The process typically involves ball bonding to bond a wire to a bond pad on the semiconductor die. A ball is created at one end of the wire, followed by bonding the ball to the bond pad using one or more methods, such as heat, scrubbing action, pressure, and ultrasonic vibrations. Afterward, the wire is drawn to another bond pad or a lead of a package substrate, and another bond is created thereon. Wirebonding provides the necessary electrical paths for signals and power.

### SUMMARY

In an example, a semiconductor die in a semiconductor package is provided. The semiconductor die includes a bond pad and a wire attached to the bond pad by an intermetallic compound. A first portion of the wire in direct contact with the bond pad has a first perimeter, a second portion of the wire not in direct contact with the bond pad has a second perimeter that is smaller than the first perimeter, a third portion of the wire between the first portion and the second portion has a third perimeter, and a first Euclidean distance between two opposing points on the third perimeter is longer than a second Euclidean distance between two other opposing points on the third perimeter.

In another example, a semiconductor package is provided. The semiconductor package includes a semiconductor die having a first bond pad; a substrate having a second bond pad; and a wire coupling the first bond pad and the second bond pad, the wire having a first end at the first bond pad and a second end at the second bond pad. The first end is a ball-bond having a circular perimeter, the second end is a wedge-bond, and the ball-bond is mechanically coupled to the first bond pad by intermetallic compound having a noncircular perimeter. A first Euclidean distance between two opposing points on the noncircular perimeter is longer than a second Euclidean distance between two other opposing points on the noncircular perimeter.

In another example, a method for coupling a semiconductor die to a substrate is provided. The method includes aligning a hollow capillary head over a bond pad on a semiconductor die; feeding a wire through the hollow capillary head to extend outside the first end; forming a ball at a tip of the wire outside the first end of the hollow capillary head; pressing down on the ball with the hollow capillary head such that the ball contacts the bond pad and deforms; and applying ultrasonic energy at the flared portion of the hollow capillary head to form a ball bond with the bond pad on the semiconductor die. The hollow capillary head has a first end and a second end with an outer surface and an inner surface between the first end and the second end, the inner surface has a tapered portion, a cylindrical portion and a flared portion, the flared portion is between the first end and the cylindrical portion, the cylindrical portion is between the flared portion and the tapered portion, the tapered portion has a smaller diameter at the cylindrical portion than at the second end, and the flared portion has a noncircular perimeter at the first end, wherein a first Euclidean distance between two opposing points on the noncircular perimeter is longer than a second Euclidean distance between two other opposing points on the noncircular perimeter.

### BRIEF DESCRIPTION OF THE DRAWINGS

Examples will be readily understood by the following detailed description in conjunction with the accompanying drawings. To facilitate this description, like reference numerals designate like elements. Various aspects are illustrated by way of example, and not by way of limitation, in the figures of the accompanying drawings.

FIGS. 1A-1B are simplified diagrams illustrating a perspective view and a cross-sectional view respectively, of a portion of an example capillary head with noncircular cone for wirebonding in semiconductor package manufacturing.

FIGS. 2A-2C are simplified diagrams illustrating a top view and cross-sectional views of an example ball bond fabricated using an example capillary head with noncircular cone for wirebonding in semiconductor package manufacturing.

FIG. 3 is a simplified top view of an example bond pad with intermetallic compound thereon formed with an example capillary head with noncircular cone for wirebonding in semiconductor package manufacturing.

FIG. 4 is a simplified top view of another example bond pad with intermetallic compound thereon formed with an example capillary head with noncircular cone for wirebonding in semiconductor package manufacturing.

FIG. 5 is a simplified graph showing performance under shear test for two different types of ball bonds.

FIG. 6 is a simplified graph showing intermetallic compound debonding performance for two different types of ball bonds.

FIG. 7 is a simplified cross-sectional view of an example operation in a wirebonding process using an example capillary head with noncircular cone as described herein.

FIG. 8 is a simplified cross-sectional view of another example operation in a wirebonding process using an example capillary head with noncircular cone as described herein.

FIG. 9 is a simplified cross-sectional view of yet another example operation in a wirebonding process using an example capillary head with noncircular cone as described herein.

FIGS. 10A-10B are simplified cross-sectional views of yet another example operation in a wirebonding process using an example capillary head with noncircular cone as described herein.

FIGS. 11A-11B are simplified cross-sectional views of yet another example operation in a wirebonding process using an example capillary head with noncircular cone as described herein.

FIG. 12 is a simplified cross-sectional view of yet another example operation in a wirebonding process using an example capillary head with noncircular cone as described herein.

FIG. 13 is a simplified flow diagram illustrating various example wirebonding operations associated with an example capillary head with noncircular cone as described herein.

FIGS. 14A-14C are simplified diagrams illustrating perspective views of details of an example semiconductor package including wirebonds formed with an example capillary head with noncircular cone.

### DETAILED DESCRIPTION

For purposes of illustrating the examples described herein, it is important to understand certain terminology and operations of semiconductor packages. The following foundational information may be viewed as a basis from which various technical aspects described in the present disclosure may be properly explained. Such information is offered for purposes of explanation only and, accordingly, should not be construed in any way to limit the broad scope of the technology presented herein and its potential applications.

In the following detailed description, various aspects of the illustrative implementations may be described using terms commonly employed by those skilled in the art to convey the substance of their work to others skilled in the art.

The term “integrated circuit” (also referred to as IC) means a circuit that is integrated into a monolithic semiconductor or analogous material. A “die” or “semiconductor die” refers to a piece of semiconductor or analogous material (e.g., silicon, gallium nitride, etc.), that contains an IC or other electronic components. The terms “package” and “IC package” are synonymous, as are the terms “die” and “IC die.” Note that the terms “chip,” “die,” and “IC die” may be used interchangeably herein.

The terms “circuit” and “circuitry” mean one or more passive and/or active electrical and/or electronic components that are arranged to cooperate with one another to provide a desired function. The terms also refer to analog circuitry, digital circuitry, hard wired circuitry, optical circuitry, programmable circuitry, microcontroller circuitry and/or any other type of physical hardware electrical and/or electronic component.

The term “package substrate” or “substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB), glass, ceramic, silicon, silicon carbide, aluminum nitride, alumina, etc. In addition, as used herein, a package substrate may refer to a substrate that includes buildup layers (e.g., Ajinomoto build-up film ® (ABF) layers). Further, the package substrate may comprise a conductive leadframe with leadfingers. In yet other examples, the substrate may comprise disjointed conductive pieces (e.g., die pad, bond pads, leadfingers, etc.) enmeshed in a dielectric material, such as mold compound and polyimide films. Packages may also include organic or inorganic passivation layers between the bare die and the substrate.

The term “noncircular cone” refers to a three-dimensional shape that is a circular on one end and noncircular on the other end. An example of a noncircular cone is an elliptical cone, with a circle on one end and an ellipse on the other end.

The term “tapered” refers to a gradual narrowing or reduction of a surface area (e.g., inner surface area of a capillary head) of an object (e.g., capillary head) from one end (e.g., end proximate to the attachment of the capillary head to the wirebonding apparatus) to an opposite end (e.g., at opening of the capillary head proximate to the semiconductor die) along the length of the object. The term “flared” refers to a gradual broadening or increase of the surface area from one end to the other opposite end along the length of the object. As used herein with respect to a capillary head, the narrowing or broadening is in a direction from an end proximate to the wirebonding apparatus to which the capillary head is attached towards the opening in the capillary head proximate to the semiconductor die.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments. “Embodiment,” “aspect” and “example” are used interchangeably herein to describe particular versions, alternatives, constructions, implementations, configurations, arrangements, methods, processes and the like.

Where the disclosure or claims recite “a,” “an,” “a first,” or “another” element, or the equivalent thereof, it should be interpreted to include one or more than one such element, neither requiring nor excluding two or more such elements. Furthermore, the terms “comprising,” “including,” “having,” and the like, as used with respect to embodiments of the present disclosure, are synonymous. To the extent that the term “includes” is used in either the detailed description or the claims, such term is intended to be inclusive in a manner similar to the term “comprising” as “comprising” is interpreted when employed as a transitional word in a claim. The term “based on” is interpreted to mean based at least in part on.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer over or under another layer may be directly in contact with the other layer or may have one or more intervening layers. Moreover, one layer between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature between two features may be in direct contact with the adjacent features or may have one or more intervening layers.

The term “between,” when used with reference to measurement ranges, is inclusive of the ends of the measurement ranges.

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale. In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using suitable characterization tools such as scanning electron microscopy (SEM), transmission electron microscope (TEM), or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging. All such non-idealized and realistic possibilities are intended to be included in the scope of the various examples described herein.

Note that in the figures, various components are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments. Note also that in cross-sectional views, some components shown as touching each other need not touch each other at all; they may be in different planes with intervening material removed. Thus, unless specifically described as being conductively coupled, surfaces shown to be touching each other may, in fact, have intervening material that is not shown for ease of illustration.

Further, unless otherwise specified, the structures shown in the figures may take any suitable form or shape according to material properties, fabrication processes, and operating conditions.

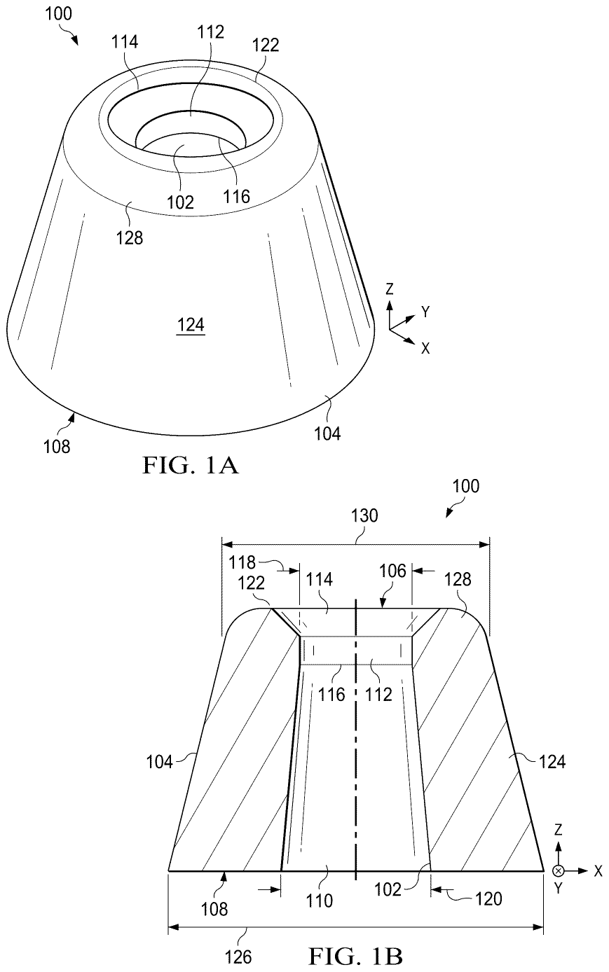

For convenience, if a collection of drawings designated with different letters are present (e.g., FIGS. 1A-1B), such a collection may be referred to herein without the letters (e.g., as “FIG. 1”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Wirebonding uses a capillary head through which the wire used for bonding is fed. The capillary head serves to situate the wire on the bond pad, and hold it in place as heat, pressure, etc. are applied to form the bond. The bond is created by formation of an intermetallic compound (IMC) in which the metal of the wire mixes with the metal of the bond pad at a molecular or crystalline level to create an adhesive bond. In general, scrub (back and forth and/or sideways motion of the capillary head) and ultrasonic generation (USG) steps are used during the wirebonding process to get better bonding strength between the wire and the bond pad. However, using both processes tends to increase the overall bonding time per bond pad. In particular, the scrubbing process has an initial accelerate mode and a final decelerate mode that together tends to add to the actual scrubbing time. For example, if the scrub cycle is set at a frequency of 300 Hz, the actual scrub time ends up as 10 ms, instead of 3 ms, with approximately two-thirds of the scrub cycle being wasted in the accelerate and decelerate modes.

On the other hand, if only ultrasonic energy is used, the bond strength between the ball and the bond pad is low, based on the prevalence of non-stick-on-pad (NSOP) or debonding of the ball that is seen from actual use or experiments. This issue arises because of the way ultrasonic energy is applied on the wire through the capillary head. Ultrasonic energy in wire bonding is generated using a piezoelectric transducer, which is electrically excited by an alternating current (AC) signal. The AC signal causes the piezoelectric material to vibrate along a single axis, generating high-frequency mechanical vibrations at ultrasonic frequencies, typically in the range of 20 kHz to 100 kHz. These vibrations are transferred from the transducer to a horn, which amplifies the ultrasonic vibrations. The horn directs the ultrasonic energy to the capillary head through which the wire is placed. The ultrasonic energy is transferred to the wire through the contact area between the capillary head and the wire. Perhaps due to the fixed directi1on of the vibrations (e.g., back and forth or sideways, but not both), the intermetallic compound generated during the bonding process using only ultrasonic vibrations (without scrubbing) tends to have higher shear strength in one direction than another.

Accordingly, a capillary head with a modified interior shape is disclosed herein to enable wirebonding using ultrasonic vibrations without scrubbing, in some example operations. FIGS. 1A-1B are simplified diagrams illustrating a perspective view and a cross-sectional view respectively, of a portion of an example capillary head 100 with noncircular cone for wirebonding in semiconductor package manufacturing. Capillary head 100 is hollow, with an inner surface 102 and an outer surface 104 between a first end 106 and a second end 108. Inner surface 102 has a tapered portion 110, a cylindrical portion 112, and a flared portion 114, which is in the shape of a noncircular cone. As can be seen in FIG. 1B, flared portion 114 is between first end 106 and cylindrical portion 112; cylindrical portion 112 is between flared portion 114 and tapered portion 110. Cylindrical portion 112 has a substantially circular perimeter 116 with a diameter 118. Tapered portion 110 has a diameter 120 at second end 108 that is larger than diameter 118. Tapered portion 110 is tapered from second end 108 towards first end 106. Flared portion 114 has a noncircular perimeter 122 at first end 106. Flared portion 114 is flared from cylindrical portion 112 towards first end 106. In some examples, noncircular perimeter 122 is substantially an ellipse. Outer surface 104 has a tapered portion 124 with a diameter 126 at second end 108. A rounded portion 128 is between first end 106 and tapered portion 124. Tapered portion 124 has another diameter 130 at rounded portion 128; diameter 130 is smaller than diameter 126. Tapered portion 124 is tapered from second end 108 towards rounded portion 128.

During operation, in various examples, a wire is fed through capillary head 100. The wire has a smaller diameter than diameter 118 of cylindrical portion 112. The tip of the wire is melted and cooled within a short time period, for example, by an electrical spark, which causes the wire to form a ball by virtue of surface tension forces on the melted wire. The diameter of the ball is typically larger than diameter 118, and smaller than diameter 130. Capillary head 100 is moved down towards the bond pad, causing the ball to be squashed against the bond pad and extrude upwards to come in contact with surface of flared portion 114. In other words, capillary head 100 contacts the wire approximately along flared portion 114. When capillary head 100 is subjected to ultrasonic vibrations, the energy is transferred to the wire through flared portion 114. In various experiments it was found that the IMC formed between the bond pad and the wire is in the shadow of noncircular perimeter 122 of flared portion 114 and has substantially the same perimeter as noncircular perimeter 122.

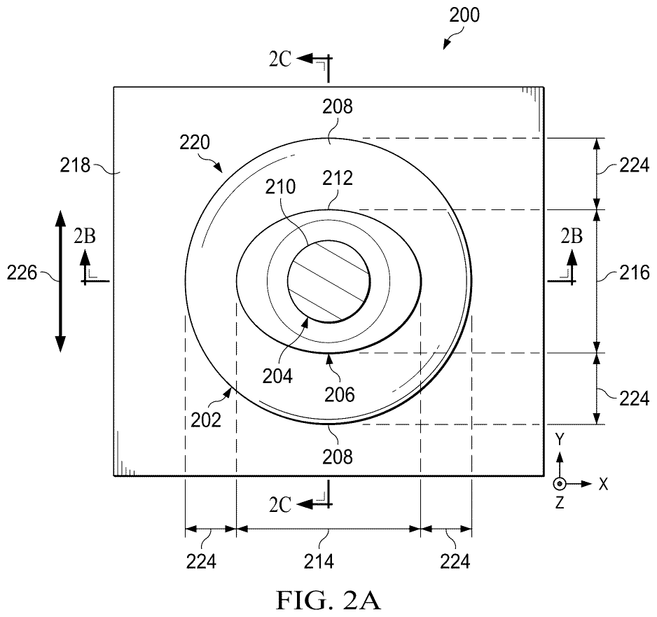

FIGS. 2A-2C are simplified diagrams illustrating a top cross-sectional view and side cross-sectional views of an example ball bond 200 fabricated using an example capillary head 100 with noncircular cone as described in FIGS. 1A-1B. FIG. 2B shows a cross-sectional view taken along axis BB′ of FIG. 2A. FIG. 2C shows a cross-sectional view taken along axis CC′ of FIG. 2A. Ball bond 200 has a first portion 202, a second portion 204 and a third portion 206. One end of the wire terminates in first portion 202 and another end (not shown) terminates in another portion on another bond pad on the substrate. First portion 202 has a first perimeter 208 representing the outermost perimeter thereof. In various examples, first perimeter 208 is substantially circular. Second portion 204 has a second perimeter 210 at a junction with third portion 206. In various examples, second perimeter 210 is substantially circular. Circular perimeter is also substantially similar to circular perimeter 116 of capillary head 100 as described in FIGS. 1A-1B.

Third portion 206 has a noncircular perimeter 212 at a junction with first portion 202. Noncircular perimeter 212 is substantially similar to noncircular perimeter 122 of capillary head 100 as described in FIGS. 1A-1B. In some examples, a first Euclidean distance 214 (e.g., straight line distance) between two opposing points (e.g., points located opposite to each other across a focus or center of the perimeter) on noncircular perimeter 212 is longer than a second Euclidean distance 216 between two other opposing points on noncircular perimeter 212. In an example, noncircular perimeter 212 is an ellipse; first Euclidean distance 214 is the major diameter of the ellipse; and second Euclidean distance 216 is the minor diameter of the ellipse. In various examples, a ratio of first Euclidean distance 214 to second Euclidean distance 216 is 38/32. In various examples, first Euclidean distance 214 may range between 37 microns and 40 microns and second Euclidean distance 216 may range between 31 microns and 34 microns. In one example, first Euclidean distance 214 may be 38 microns and second Euclidean distance 216 may be 32 microns.

Ball bond 200 is formed between bond pad 218 and wire 220 through IMC 222. In various examples, bond pad 218 comprises copper, gold, or aluminum. Wire 220 comprises gold or aluminum in some examples. IMC 222 comprises a mixture of the materials of bond pad 218 and wire 220. For example, where a gold wire is bonded to an aluminum bond pad, the primary IMC formed includes AuAl₂. When a gold wire is wirebonded to a copper pad, the primary IMC includes AuCu, which is a mixture of gold and copper atoms, with potential variations in composition depending on the specific bonding conditions and the relative diffusion rates of the metals involved. Where a copper pad is wirebonded with an aluminum wire, the resulting IMC may include CuAl₂, CuAl, and Cu₉Al₄.

IMC 222 is substantially in the shadow of noncircular perimeter 212 and follows the same shape. For example, a perimeter of IMC 222 is substantially same as noncircular perimeter 212. A fourth portion 224 of wire 220 forming a part of first portion 202 is between first perimeter 208 and noncircular perimeter 212. Fourth portion 224 extends beyond IMC 222 and is not directly coupled to bond pad 218. In various examples, the ultrasonic energy is applied in a direction 226 represented by a double-headed arrow in FIG. 2A. In some examples, direction 226 is perpendicular to first Euclidean distance 214 such that noncircular perimeter 212 is elongated in a direction perpendicular to the direction of the ultrasonic vibrations. In examples in which noncircular perimeter 212 is an ellipse, direction 226 is perpendicular to the major axis of the ellipse.

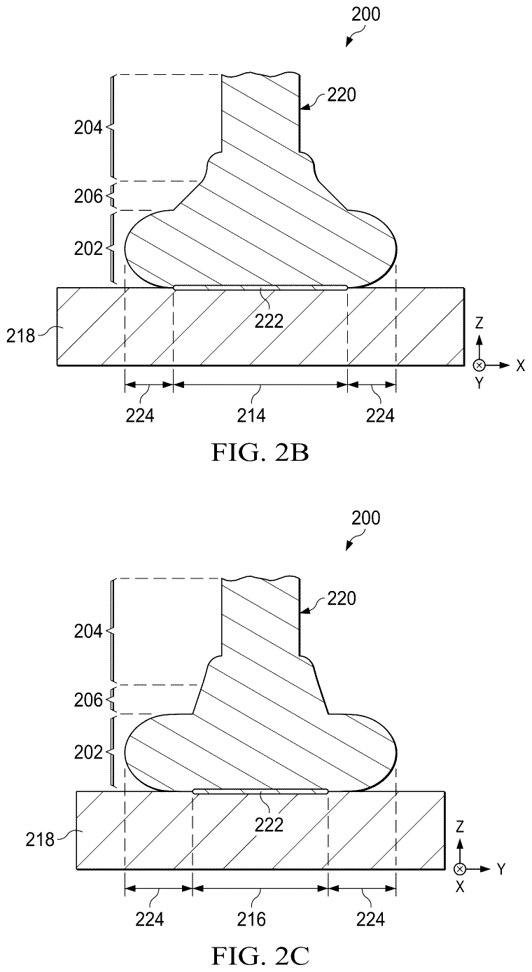

FIG. 3 is a simplified top view of an example bond pad 300 with IMC 302 thereon formed with an example capillary head 100 with noncircular cone as described in FIGS. 1A-1B. In the example shown, bond pad 300 is rectangular in shape. IMC 302 has a noncircular perimeter 304, which is substantially similar to noncircular perimeter 122 of capillary head 100. In some examples, a first Euclidean distance 306 between two opposing points on noncircular perimeter 304 is longer than a second Euclidean distance 308 between two other opposing points on noncircular perimeter 304. In an example, noncircular perimeter 304 is an ellipse; first Euclidean distance 306 is the major diameter of the ellipse; and second Euclidean distance 308 is the minor diameter of the ellipse. In various examples, a ratio of first Euclidean distance 306 to second Euclidean distance 308 is 38/32. In various examples, first Euclidean distance 214 may range between 37 microns and 40 microns and second Euclidean distance 216 may range between 31 microns and 34 microns. In one example, first Euclidean distance 214 may be 38 microns and second Euclidean distance 216 may be 32 microns. The ball-bond (not shown) has a perimeter 310 (shown in dotted line). In some examples, perimeter 310 is substantially circular.

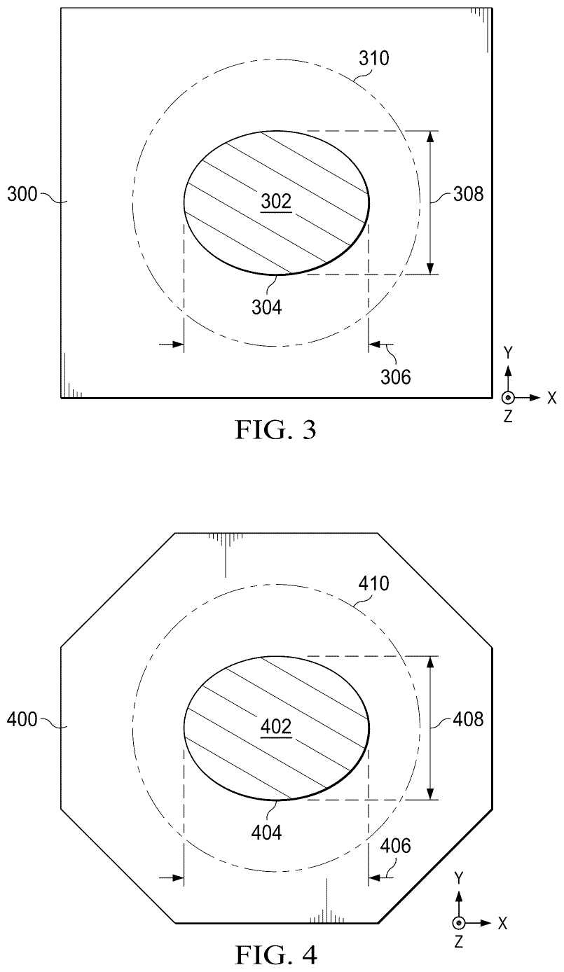

FIG. 4 is a simplified top view of an example bond pad 400 with IMC 402 thereon formed with an example capillary head 100 with noncircular cone as described in FIGS. 1A-1B. In the example shown, bond pad 400 is octagonal in shape. Note that other shapes of bond pads, such as circular and other polygonal shapes may also be included without departing from the scope of the various examples. IMC 302 has a noncircular perimeter 404, which is substantially similar to noncircular perimeter 122 of capillary head 100. In some examples, a first Euclidean distance 406 between two opposing points on noncircular perimeter 404 is longer than a second Euclidean distance 408 between two other opposing points on noncircular perimeter 404. In an example, noncircular perimeter 404 is an ellipse; first Euclidean distance 406 is the major diameter of the ellipse; and second Euclidean distance 408 is the minor diameter of the ellipse. In various examples, a ratio of first Euclidean distance 406 to second Euclidean distance 408 is 38/32. In various examples, first Euclidean distance 214 may range between 37 microns and 40 microns and second Euclidean distance 216 may range between 31 microns and 34 microns. In one example, first Euclidean distance 214 may be 38 microns and second Euclidean distance 216 may be 32 microns. The ball-bond (not shown) has a perimeter 410 (shown in dotted line). In some examples, perimeter 410 is substantially circular. In examples in which bond pad 400 is a shape that is not rectangular, first Euclidean distance 214 may be aligned to conform to an axis (e.g., diagonal, midline, etc.) so that the shear strength of the resultant ball bond is higher than for a rectangular bond pad. In standard ball bonds, the IMC has a circular perimeter, and its alignment with respect to the bond pad would not affect the shear strength of the ball bond. With noncircular IMC 302 on a non-rectangular bond pad as in the example described herein, various different alignment scenarios may be strength-tested and an optimized alignment may be selected based on the performance of the ball bond. In various such examples, different bond pad shapes may result in different optimized alignment directions of the ball bond.

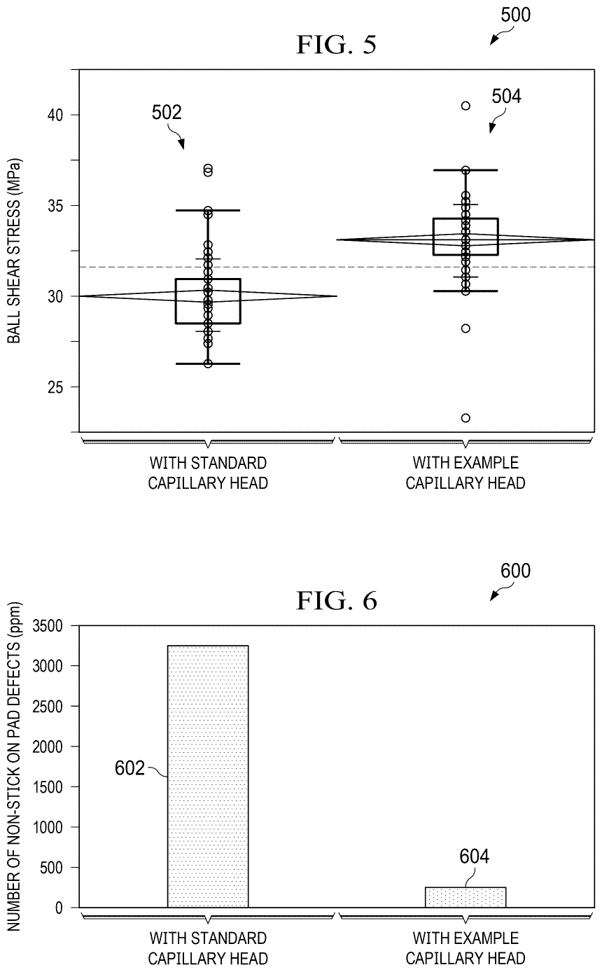

FIG. 5 is a simplified graph 500 showing performance under shear test for two different types of ball bonds, one made with a standard capillary head and another made with example capillary head 100 with noncircular cone as described in FIGS. 1A-1B. Ball shear values in megapascals are provided along the Y-axis and indicate the shear strength of the bond. For example, the ball shear value is the shear stress at which the ball-bond delaminates from the bond pad. Ball shear values 502 represent the shear strength of bonds made using a standard capillary head. Ball shear values 504 represent the shear strength of bonds made using example capillary head 100. Ball shear values 504 has greater average value than ball shear values 502, suggesting that the shear strength of bonds made using example capillary head 100 is greater than the shear strength of bonds made using a standard capillary head.

The noncircular cone of flared portion 114 of capillary head 100 as described in FIGS. 1A-1B creates a corresponding noncircular cone shape of the ball bond in contact therewith. Due to the noncircular cone surface of capillary head 100 being in contact with the corresponding noncircular cone surface of the ball bond, ultrasonic energy is transferred to the ball bond along the flared portion thereof in third portion 206 as described in FIGS. 2A-2C. Further, noncircular perimeter 122 of flared portion 114 of capillary head 100 facilitates forming the IMC in its shadow with a substantially similar shape. In the example used to generate the test data in FIG. 5, the noncircular shape is substantially an ellipse. This elliptical area is larger than the circular area of the IMC created with a standard circular capillary head having the same diameter as the minor axis of the ellipse. The larger elliptical area facilitates a stronger bond between the wire and the bond pad. This stronger bond is shown by the higher shear strength test data in FIG. 5.

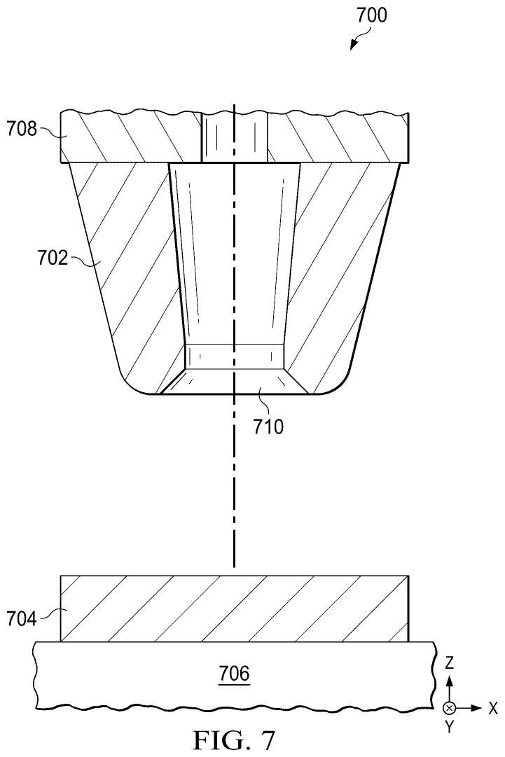

FIG. 6 is a simplified graph 600 showing intermetallic compound debonding performance for two different types of ball bonds, one made with a standard capillary head and another made with the example capillary head 100 with noncircular cone as described in FIGS. 1A-1B. The number of NSOP defects in parts per million (PPM) are provided along the Y-axis and indicate the debonding performance. Higher the NSOP, worse is the debonding performance. As can be seen from graph 600, NSOP 602 is approximately 3200 ppm for bonds made using a standard capillary head. On the other hand, NSOP 604 is less than 500 ppm for bonds made using example capillary head 100 with noncircular cone, suggesting that the debonding performance of bonds made using example capillary head 100 is significantly better than that of bonds made using a standard capillary head.

The noncircular cone of flared portion 114 of capillary head 100 as described in FIGS. 1A-1B creates a corresponding noncircular cone shape of the ball bond in contact therewith. Due to the noncircular cone surface of capillary head 100 being in contact with the corresponding noncircular cone surface of the ball bond, ultrasonic energy is transferred to the ball bond along the flared portion thereof in third portion 206 as described in FIGS. 2A-2C. Further, noncircular perimeter 122 of flared portion 114 of capillary head 100 facilitates forming the IMC in its shadow with a substantially similar shape. In the example used to generate the test data in FIG. 6, the noncircular shape is substantially an ellipse. This elliptical area is larger than the circular area of the IMC created with a standard circular capillary head having the same diameter as the minor axis of the ellipse. The larger elliptical area facilitates a stronger bond between the wire and the bond pad. This stronger bond is shown by the lower NSOP numbers in FIG. 6.

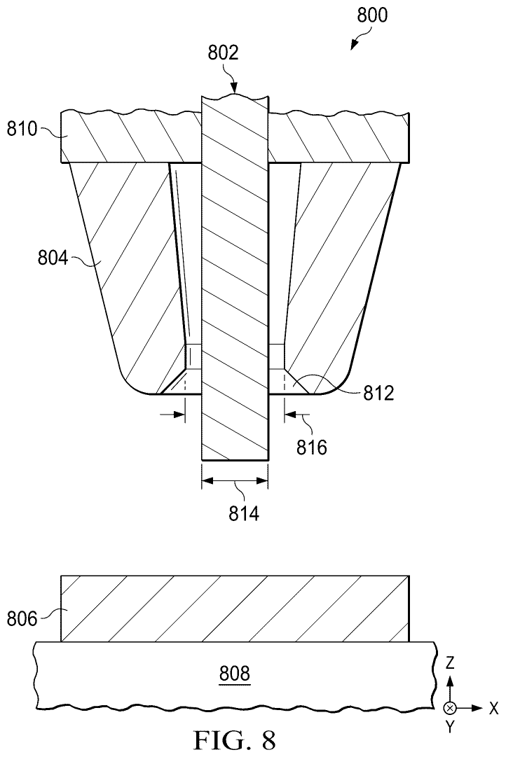

FIGS. 7-12 show various views of example operations of a wirebonding process using a capillary head with noncircular cone such as capillary head 100 described in FIGS. 1A-1B. FIG. 7 shows a cross-sectional view of example operation 700, which includes aligning a capillary head 702 over a bond pad 704 on a semiconductor die 706. Capillary head 702 is attached to a wirebonding apparatus 708 that includes the ultrasonic transducer, motors, and other components for performing the wirebonding process. Capillary head 702 includes a noncircular cone 710 as described in reference to flared portion 114 of FIGS. 1A-1B.

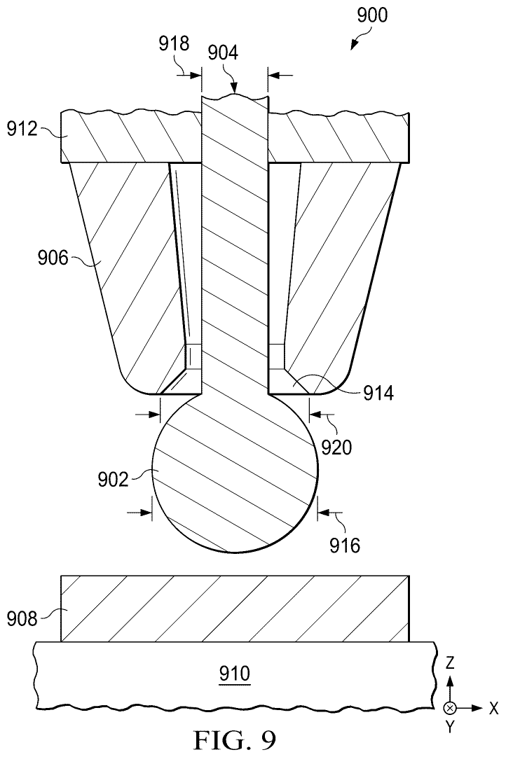

FIG. 8 shows a cross-sectional view of example operation 800 of a wirebonding process using a capillary head with noncircular cone such as capillary head 100 described in FIGS. 1A-1B. As shown in FIG. 8, operation 800 includes feeding a wire 802 through a capillary head 804 over a bond pad 806 on a semiconductor die 808. Capillary head 804 is attached to a wirebonding apparatus 810 that includes the ultrasonic transducer, motors, and other components for performing the wirebonding process. Capillary head 804 includes a noncircular cone 812 as described in reference to flared portion 114 of FIGS. 1A-1B. Wire 802 has a diameter 814 that is less than the smallest internal diameter 816 of capillary head 804.

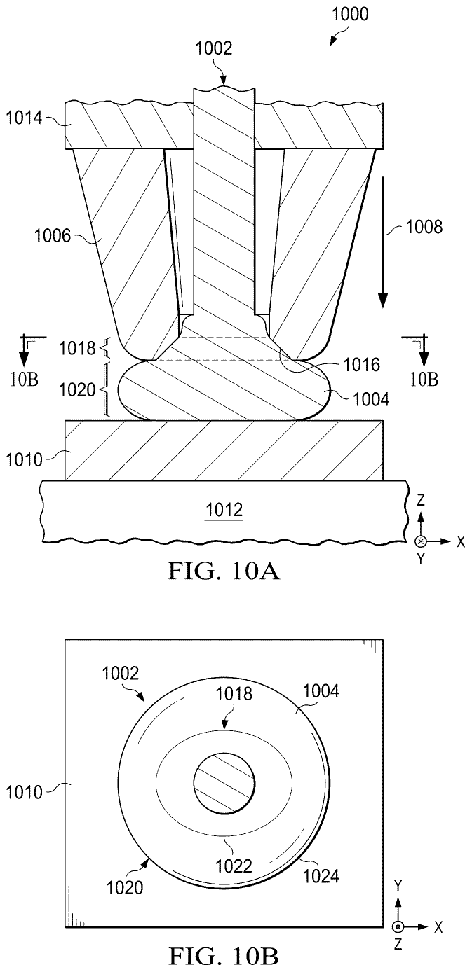

FIG. 9 shows a cross-sectional view of example operation 900 of a wirebonding process using a capillary head with noncircular cone such as capillary head 100 described in FIGS. 1A-1B. As shown in FIG. 9, operation 900 includes forming a ball 902 at a tip of a wire 904. Wire 904 is within a capillary head 906 aligned over a bond pad 908 on a semiconductor die 910. In various examples, ball 902 may be formed by locally heating the tip, for example, using high voltage impulse signal on wire 904 or localized heating at the tip of wire 904 or by any other suitable method. Capillary head 906 is attached to a wirebonding apparatus 912 that includes the ultrasonic transducer, motors, and other components for performing the wirebonding process. Capillary head 906 includes a noncircular cone 914 as described in reference to flared portion 114 of FIGS. 1A-1B. Ball 902 has a diameter 916 that is greater than diameter 918 of wire 904 and maximum span 920 of noncircular cone 914. Maximum span 920 corresponds to the largest Euclidean distance between any two opposing points around a perimeter of noncircular cone 914. In examples in which the perimeter is an ellipse, maximum span 920 is the major diameter of the ellipse. In such examples, diameter 916 of the ball is greater than the major diameter of the ellipse.

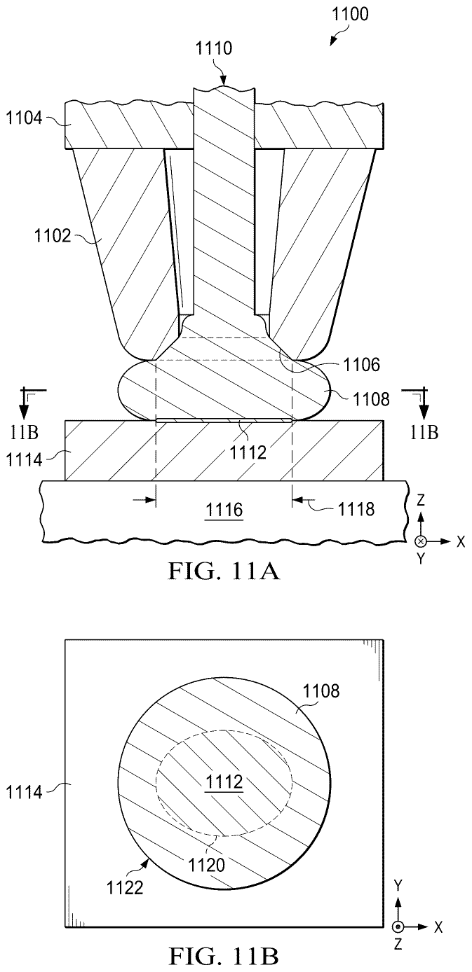

FIG. 10A shows a cross-sectional view of example operation 1000 of a wirebonding process using a capillary head with noncircular cone such as capillary head 100 described in FIGS. 1A-1B. As shown in FIG. 10A, operation 1000 includes pressing down on the ball at tip of wire 1002 into a deformed ball 1004 by moving capillary head 1006 in a direction 1008 towards bond pad 1010 on semiconductor die 1012 until wire 1002 is in direct contact with bond pad 1010. Capillary head 1006 is attached to a wirebonding apparatus 1014 that includes the ultrasonic transducer, motors, and other components for performing the wirebonding process. Capillary head 1006 includes a noncircular cone 1016 as described in reference to flared portion 114 of FIGS. 1A-1B. At the end of this operation 1000, deformed ball 1004 is peripherally in contact with substantially all surface area of noncircular cone 1016 in the region indicated by the dotted lines. A portion 1018 of deformed ball 1004 within capillary head 1006 may conform to the inner surface of capillary head 1006 corresponding to noncircular cone 1016. Another portion 1020 of deformed ball 1004 outside capillary head 1006 may have a perimeter larger than the noncircular perimeter of noncircular cone 1016.

A top view of cross-section taken along axis BB′ is shown in FIG. 10B with capillary head 1006 and semiconductor die 1012 removed for ease of illustration and explanation. Portion 1018 has a noncircular perimeter 1022. In some examples, noncircular perimeter 1022 is an ellipse. Portion 1020 has a perimeter 1024. In various examples, perimeter 1024 is substantially circular.

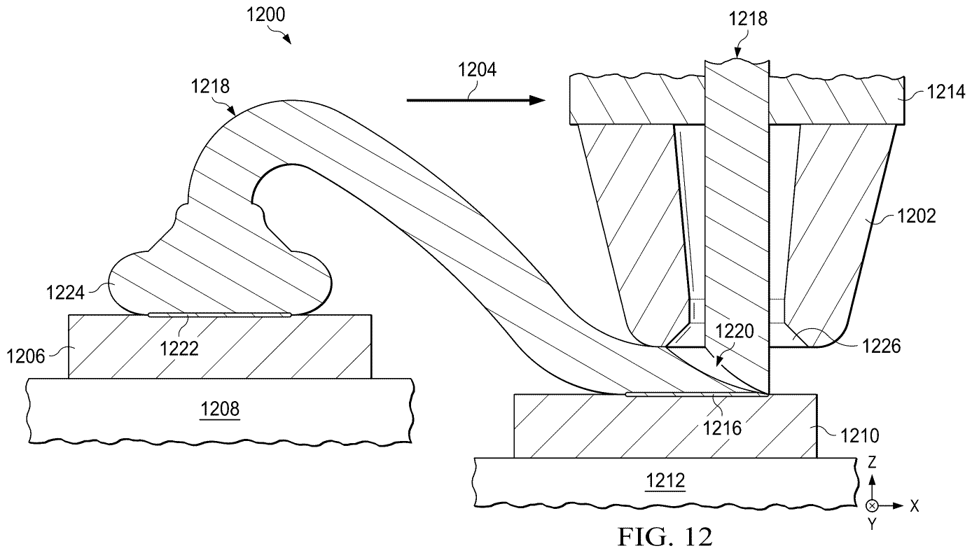

FIG. 11A shows a cross-sectional view of example operation 1100 of a wirebonding process using a capillary head with noncircular cone such as capillary head 100 described in FIGS. 1A-1B. As shown in FIG. 11A, operation 1100 includes applying ultrasonic energy on capillary head 1102. Capillary head 1102 is attached to a wirebonding apparatus 1104 that includes the ultrasonic transducer, motors, and other components for performing the wirebonding process. Substantially the entire surface area of noncircular cone 1106 of capillary head 1102 is in direct contact with deformed ball 1108 of wire1110, so that the ultrasonic vibrations of capillary head 1102 are transferred to deformed ball 1108 through noncircular cone 1106. Note that in various examples, a perimeter of noncircular cone 1106 is an ellipse and the direction of the ultrasonic vibrations is perpendicular to the major diameter of the ellipse. In examples wherein the perimeter of noncircular cone 1106 is not exactly an ellipse, the direction of ultrasonic vibrations is perpendicular to the axis along which lies the largest Euclidean distance between two opposing points on the noncircular perimeter. The ultrasonic vibrations cause IMC 1112 to develop in an area of contact between deformed ball 1108 and bond pad 1114 of semiconductor die 1116. Due to the lack of any additional scrubbing process, the IMC 1112 develops directly in a shadow 1118 of noncircular cone 1106.

A top view of cross-section taken along axis BB′ is shown in FIG. 11B with capillary head 1102 and semiconductor die 1116 removed for ease of illustration and explanation. A perimeter 1120 (shown in dotted line to indicate that it is underneath the cross-sectional plane) of IMC 1112 substantially corresponds to the noncircular perimeter (e.g., elliptical perimeter) of noncircular cone 1106. Note that perimeter 1120 of IMC 1112 is also substantially identical to noncircular perimeter 1022 discussed in reference to FIG. 10B. IMC 1112 causes a direct physical coupling (e.g., adhesion) of wire 1110 with bond pad 1114. As a result, a portion 1122 (shown in a different hatching) of deformed ball 1108 that is not in shadow 1118 of noncircular cone 1106 may not be directly coupled to bond pad 1114.

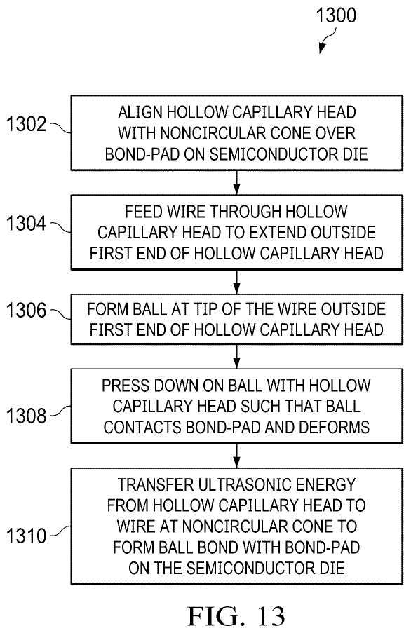

FIG. 12 shows a cross-sectional view of example operation 1200 of a wirebonding process using a capillary head with noncircular cone such as capillary head 100 described in FIGS. 1A-1B. As shown in FIG. 12, operation 1200 includes moving capillary head 1202 in a direction 1204 away from bond pad 1206 on semiconductor die 1208 to align with another bond pad 1210 on a substrate 1212 to which semiconductor die 1208 is attached (e.g., with die attach or other adhesive). Note that semiconductor die 1208 is not shown attached to substrate 1212 merely for ease of illustration and due to the fact that the drawing is not to scale. Substrate 1212 may be a leadframe in some examples. In other examples, substrate 1212 may be an organic substrate with built-up dielectric layers and metallization therebetween. Capillary head 1202 is attached to a wirebonding apparatus 1214 that includes the ultrasonic transducer, motors, and other components for performing the wirebonding process. Ultrasonic energy and/or scrubbing may be applied to capillary head 1202 to cause IMC 1216 to form between wire 1218 and bond pad 1210. Thereafter capillary head 1202 is moved to cause wire 1218 to be cut such a wedge-shaped bond 1220 (e.g., wedge-bond) is formed on bond pad 1210, completing the formation of a wire-bond between bond pad 1206 on semiconductor die 1208 and bond pad 1210 on substrate 1212.

In various examples, IMC 1222 formed between one end of wire 1218 and bond pad 1206 has a noncircular perimeter (e.g., ellipse) whereas ball-bond 1224 (e.g., deformed ball) may have a substantially circular perimeter. IMC 1216 formed between the other end of wire 1218 and bond pad 1210 may have any suitable shape depending on whether only ultrasonic energy was applied (in which case, the perimeter may follow at least partially, a shadow of noncircular cone 1226 of capillary head 1202), or whether scrubbing was also applied (in which case, the shape may vary based on the direction of the scrubbing).

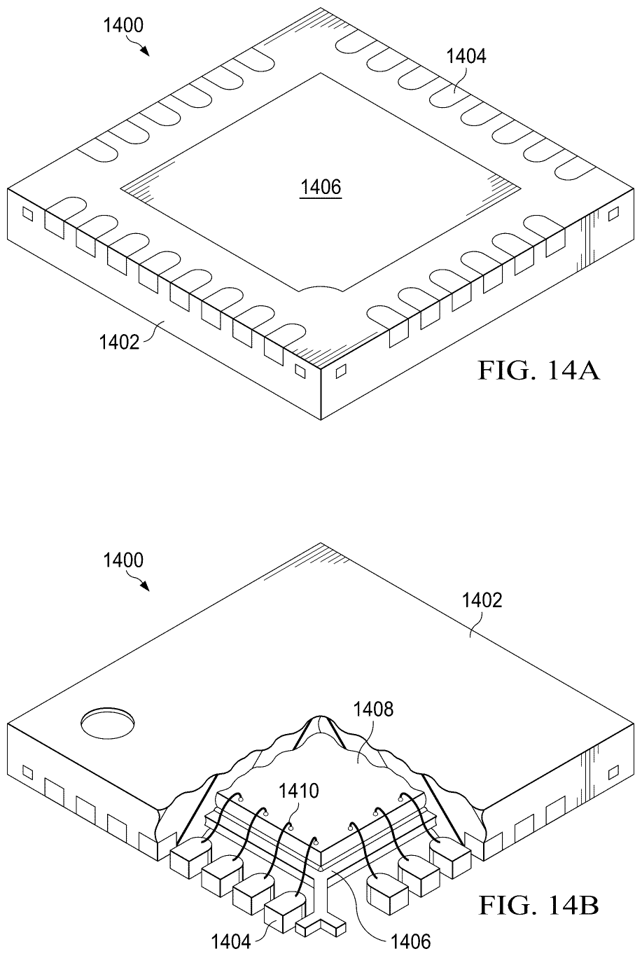

FIG. 13 is a simplified flow diagram illustrating various example wirebonding operations 1300 associated with example capillary head 100 with noncircular cone as described herein in FIG. 1A-1B. At 1302, a hollow capillary head (e.g., capillary head 100) is aligned over a bond pad (e.g., bond pad 704) on a semiconductor die (e.g., semiconductor die 706). Hollow capillary head 100 has the shape and geometry as described in reference to FIGS. 1A-1B. At 1304, a wire (e.g., wire 802) may be fed through the hollow capillary head to extend outside the capillary head. At 1306, a ball (e.g., ball 902) may be formed at a tip of the wire outside the hollow capillary head. At 1308, the ball may be pressed down with the hollow capillary head such that the ball contacts the bond pad and deforms into a deformed shape (e.g., deformed ball 1004). At 1310, ultrasonic energy may be applied at the flared portion (e.g., noncircular cone) of the hollow capillary head such that the ultrasonic energy is transferred from the hollow capillary head at the noncircular cone to a ball bond with the bond pad on the semiconductor die.

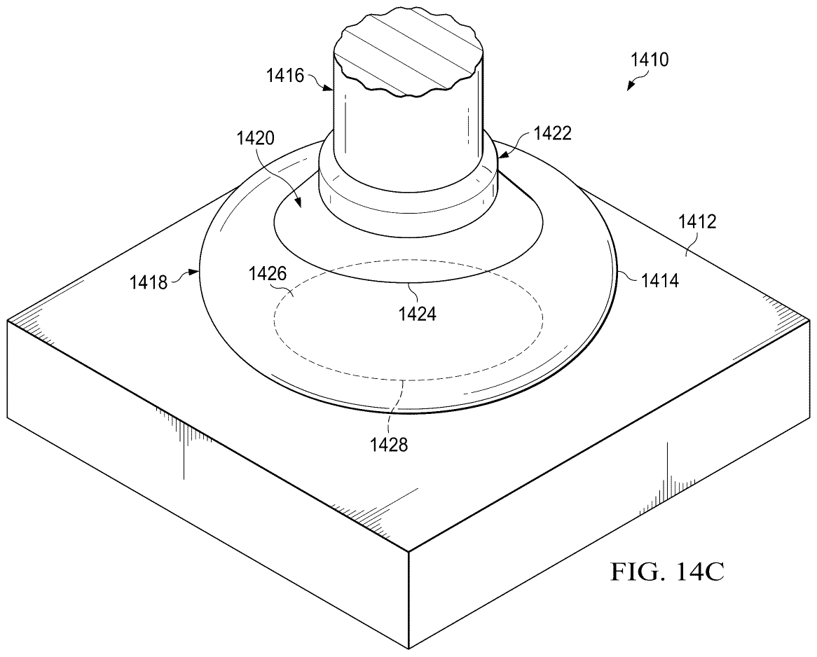

FIGS. 14A-14C are simplified diagrams illustrating perspective views of various details of an example semiconductor package 1400. Semiconductor package 1400 includes mold compound 1402 and conductive leads 1404 on a substrate1406. In the example shown, semiconductor package 1400 is a quad flat no lead (QFN) package. The description herein may also be applicable to various other types of semiconductor packages that use wirebonding for electrically connecting a semiconductor die with a substrate, such as dual in-line package (DIP), surface mount device packages (e.g., chip on board (COB), small outline integrated circuit (SOIC)), ball grid array (BGA), plastic leaded chip carrier (PLCC), pin grid array (PGA), etc.

As shown in the cut-out perspective view of FIG. 14B, a semiconductor die 1408 may be enclosed by mold compound 1402. In some examples, conductive leads 1404 may be leadfingers of substate 1406, which may be a leadframe. In the example shown, substate 1406 includes a thermal pad that also facilitates mounting semiconductor die 1408 thereon. In some other examples, the thermal pad may simply be a die pad. In yet other examples, the thermal pad or die pad may be absent in semiconductor package 1400. A plurality of wirebonds 1410 provide electrical connectivity between semiconductor die 1408 and conductive leads 1404. Wirebonds 1410 may be formed with an example capillary head 100 having a noncircular cone as described in reference to FIGS. 1A-1B.

A portion of an example one of wirebonds 1410 is shown in further detail in perspective view in FIG. 14C. Bond pad 1412 is on semiconductor die 1408. Wirebonds 1410 includes a ball bond 1414 at an end of wire 1416. Another end of wire 1416 (not shown) is coupled to one of conductive leads 1404. Ball bond 1414 includes a first portion 1418, a second portion 1420, and a third portion 1422. The junction of first portion 1418 and second portion 1420 forms a noncircular perimeter 1424 substantially similar to noncircular perimeter 212 described in FIG. 2A. The surface of second portion 1420 is also substantially similar to flared portion 114 described in FIGS. 1A-1B, and is a noncircular cone. In various examples, the junction of second portion 1420 and third portion 1422 may be a circular perimeter (not labeled to prevent clutter). Ball bond 1414 may be physically coupled (e.g., attached, adhered, etc.) to bond pad 1412 by IMC 1426 having a noncircular parameter 1428 that is substantially similar to noncircular perimeter 1424. In various examples, noncircular parameter 1428 may be in a shadow of noncircular perimeter 1424. Note that although only one example one of wirebonds 1410 is shown in detail, substantially all wirebonds 1410 in semiconductor package 1400 may be of similar shape and configuration, including the noncircular perimeter as described herein in respective ball bonds.

In various examples, semiconductor package 1400 may be fabricated as follows. Semiconductor die 1408 may be attached to substrate 1406 using a suitable die attach adhesive. Wirebonds 1410 may be created using example capillary head 100 as described in reference to FIGS. 1A-1B and a method as described in FIGS. 7-13. Thereafter, mold compound 1402 may be added around semiconductor die 1408 and substrate 1406, enclosing them as suitable based on particular needs. In some examples, substrate 1406 may be a leadframe and mold compound 1402 may be added to expose the thermal pad and portions of conductive leads 1404. In some other examples, mold compound 1402 may be added to expose only conductive leads 1404. Mold compound 1402 may be cured to form an assembly. The assembly may be singulated to make the semiconductor package. In some examples, substrate 1406 may be singulated from the leadframe roll to make the semiconductor package. In some other examples, mold compound 1402 may be singulated from the other surrounding packages that may be manufactured together simultaneously.

In some other examples, substrate 1406 may be an organic substrate with builtup layers and conductive lines/vias therein. In some such examples, conductive leads 1404 may comprise bond pads on the substrate, conductive lines and vias within substrate 1406 and suitable conductive contacts such as pins (of a pin grid array) or balls (of a ball grid array). In some such examples, mold compound 1402 may surround substrate 1406 on five sides, exposing the bottom portion having the pins or balls thereon. Mold compound 1402 may be singulated after curing to make the semiconductor package.

Although the present disclosure has described in detail particular arrangements and configurations, these example configurations and arrangements may be changed significantly without departing from the scope of the present disclosure. For example, although the present disclosure has been described with reference to a QFN package, the same configuration and arrangements may be applicable to other types of packages. Moreover, although the semiconductor package has been illustrated with reference to particular elements that facilitate the wirebonding processing functionalities on a semiconductor die attached to a leadframe, these elements and operations may be replaced by any other suitable architecture of semiconductor packages.

Although FIGS. 7-13 illustrate various operations which may be performed in a particular order, this is simply illustrative, and the operations discussed herein may be reordered and/or repeated as suitable. Further, additional operations which are not illustrated may also be performed without departing from the scope of the present disclosure. Also, various ones of the operations discussed herein with respect to FIGS. 7-13 may be modified in accordance with the present disclosure to form wirebonds as disclosed herein. Although various operations are illustrated in FIGS. 7-13 once each, the operations may be repeated as often as desired.

It is important to note that the operations described with reference to the preceding figures illustrate only some of the possible scenarios that may be implemented to fabricate wire-bonds. Some of these operations may be deleted or removed where appropriate, or these steps may be modified or changed considerably without departing from the scope of the discussed concepts. In addition, the timing of these operations may be altered considerably and still achieve the results taught in this disclosure. The preceding operational flows have been offered for purposes of example and discussion.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A semiconductor package comprising:
a semiconductor die including a bond pad; and
a wire attached to the bond pad by an intermetallic compound, wherein:
a first portion of the wire in direct contact with the bond pad has a first perimeter,
a second portion of the wire not in direct contact with the bond pad has a second perimeter that is smaller than the first perimeter,
a third portion of the wire between the first portion and the second portion has a third perimeter, and
a first Euclidean distance between two opposing points on the third perimeter is longer than a second Euclidean distance between two other opposing points on the third perimeter.

2. The semiconductor package of claim 1, wherein a ratio of the first Euclidean distance to the second Euclidean distance is 38/32.

3. The semiconductor package of claim 1, wherein the wire comprises at least one of gold or aluminum and the bond pad comprises at least one of copper, gold, or aluminum.

4. The semiconductor package of claim 1, wherein the semiconductor die is coupled to a substrate by the wire, a first end of the wire terminating in the first portion and a second end of the wire terminating in a fourth portion on another bond pad on the substrate.

5. The semiconductor package of claim 1, wherein:
a fourth perimeter of the intermetallic compound is substantially identical to the third perimeter, and
a fourth portion of the wire between the first perimeter and the fourth perimeter is not coupled to the bond pad.

6. The semiconductor package of claim 1, wherein the bond pad has an octagonal perimeter.

7. A semiconductor package, comprising:
a semiconductor die having a first bond pad;
a substrate having a second bond pad; and
a wire coupling the first bond pad and the second bond pad, the wire having a first end at the first bond pad and a second end at the second bond pad, wherein:
the first end is a ball-bond having a circular perimeter,
the second end is a wedge-bond, and
the ball-bond is mechanically coupled to the first bond pad by intermetallic compound having a noncircular perimeter, wherein a first Euclidean distance between two opposing points on the noncircular perimeter is longer than a second Euclidean distance between two other opposing points on the noncircular perimeter.

8. The semiconductor package of claim 7, wherein a ratio of the first Euclidean distance to the second Euclidean distance is 38/32.

9. The semiconductor package of claim 7, wherein the intermetallic compound comprises at least two from a set comprising: copper, gold and aluminum.

10. The semiconductor package of claim 7, wherein:
the noncircular perimeter is within the circular perimeter, and
a portion of the ball-bond outside the noncircular perimeter is not coupled to the first bond pad.

11. A method of making a semiconductor package, the method comprising:
aligning a hollow capillary head over a bond pad on a semiconductor die, wherein:
the hollow capillary head has a first end and a second end with an outer surface and an inner surface between the first end and the second end,
the inner surface has a first portion, a second portion and a third portion,
the third portion is between the first end and the second portion,
the second portion is between the third portion and the first portion,
the first portion has a smaller diameter at the second portion than at the second end, and
the third portion has a noncircular perimeter at the first end, wherein a first Euclidean distance between two opposing points on the noncircular perimeter is longer than a second Euclidean distance between two other opposing points on the noncircular perimeter;
feeding a wire through the hollow capillary head to extend outside the first end;
forming a ball at a tip of the wire outside the first end of the hollow capillary head;
pressing down on the ball with the hollow capillary head such that the ball contacts the bond pad and deforms; and
applying ultrasonic energy at the third portion of the hollow capillary head to form a ball bond with the bond pad on the semiconductor die.

12. The method of claim 11, wherein ultrasonic vibrations from the ultrasonic energy is in a direction perpendicular to the first Euclidean distance.

13. The method of claim 11, wherein a shape of the ball after deforming conforms to the inner surface of the hollow capillary head between the first end and the first portion.

14. The method of claim 13, wherein the shape of the ball after deforming further comprises a portion outside the hollow capillary head, the portion having a circular perimeter larger than the noncircular perimeter.

15. The method of claim 11, wherein:
the ball forms an intermetallic compound with the bond pad on the semiconductor die, and
the intermetallic compound is in a shape having the noncircular perimeter.

16. The method of claim 11, wherein:
the first portion of the hollow capillary head is a first tapered portion,
the outer surface of the hollow capillary head has a second tapered portion and a rounded portion,
the rounded portion is between the first end and the second tapered portion, and
the second tapered portion has a smaller diameter at the rounded portion than at the second end.

17. The method of claim 11, wherein the wire has a smaller diameter than the second portion of the hollow capillary head.

18. The method of claim 11, wherein the bond pad is a first bond pad, and the method further comprises:
moving the hollow capillary head to align with a second bond pad on a substrate;
mechanically coupling the wire to the second bond pad; and
cutting the wire to form a wedge-bond on the second bond pad.

19. The method of claim 18, further comprising:
adding mold compound around the semiconductor die and the substrate;
curing the mold compound to form an assembly; and
singulating the assembly to make a semiconductor package.

20. The method of claim 11, further comprising:
attaching the second end of the hollow capillary head to a wirebonding apparatus such that the first Euclidean distance of the third portion is perpendicular to a direction of ultrasonic vibrations from the ultrasonic energy.
